(19) United States
(12) Patent Application Publication
(10) Pub. No.: US 2011/0221538 A1
(43) Pub. Date: Sep. 15, 2011

(54) Piezoelectric oscillator

(75) Inventors: Mitsuaki Koyama, Sayama-shi (JP); Shigetaka Kaga, Sayama-shi (JP); Shigenori Watanabe, Sayama-shi (JP)

(73) Assignee: NIHON DEMPA KOGYO CO., LTD., Shibuya-ku (JP)

(21) Appl. No.: 12/931,794

(22) Filed: Feb. 10, 2011

(30) Foreign Application Priority Data
Mar. 10, 2010 (JP) 2010-053541

(51) Int. Cl. H03B 5/32; H03H 9/17

(52) U.S. Cl. 331/163

(57) ABSTRACT

To provide a technique capable of suppressing electric energy by a fundamental wave vibration and reducing phase noise in a piezoelectric oscillator using an overtone of a thickness shear vibration in a piezoelectric piece. An excitation electrode portion in an electrode 2 on one surface side of an AT cut crystal piece 1 is separated from each other in a direction perpendicular to a thickness shear vibration direction (in a Z′-axis direction) and separated portions are formed in parallel in a strip shape as divided electrodes 21, 22. The divided electrodes 21, 22 have end portions thereof connected to each other to be formed in an angular C-shape as a whole. An electrode 3 on the other surface side has strip-shaped excitation electrode portions 31, 32 formed at positions facing the first divided electrode 21 and the second divided electrode 22 on the one surface side respectively to be formed in an angular C-shaped electrode in the opposite direction. Accordingly, only the divided electrodes 21, 22 function as the excitation electrode portion.

### BACKGROUND OF THE INVENTION

1. Field of the Invention

The present invention relates to a piezoelectric oscillator using a piezoelectric piece generating a thickness shear vibration.

2. Description of the Related Art

A TCXO, an OCXO, an MCXO, and so on have been known in order to obtain a stable temperature characteristic in a crystal oscillator. The TCXO is to control a frequency of the crystal oscillator by using a signal of a temperature sensor. A thermistor has been used in general as the above temperature sensor, and as for the control of frequency stability, it has been said that ±0.2 ppm or so in a temperature range of −20° C. to +75° C. is a limit. The OCXO is to make an ambient temperature where a crystal resonator is placed fixed by using an oven, and has high frequency temperature stability and further can achieve low noise. However, the OCXO has large power consumption and is expensive to thus have limited uses, resulting that it has been used for, for example, a base station.

Further, the MCXO is one in which respective frequencies of a thickness shear vibration mode and a thickness torsional vibration mode to be generated by a pair of electrodes formed on one surface of, for example, an SC cut crystal are separated by a filter, and the frequency of the thickness shear vibration mode is handled as an output frequency signal and the frequency of the thickness torsional vibration mode is handled as a temperature signal, and the output frequency is controlled in accordance with the temperature signal by using a microcomputer. The above MCXO also has higher frequency stability than the TCXO, and further can achieve low noise, but has a complicated circuit configuration and large power consumption and is expensive, and thus it has not been used recently.

Furthermore, the above-described crystal resonator exhibits a stable frequency temperature characteristic in an overtone compared with in a fundamental wave vibration, so that it has also been known that an overtone is used without each of the above-described systems or in combination with each of the systems. However, electric energy by the fundamental wave vibration is also generated on an electrode, and thereby a component of the fundamental wave is applied to an output signal of the overtone, and as a result, phase noise is increased.

In Patent Document 1, there has been disclosed that two divided electrodes are approached to the extent that they are not short-circuited on a piezoelectric substrate to generate a thickness torsional vibration and front surface electrodes and electrodes on a rear surface side are series or parallel connected, which does not indicate a technique of the present invention.

[Patent Document 1] Patent Publication No. 2640936: column 8 lines 32 to 35, column 10 lines 38 to 43, column 13 lines 43 to 47, FIG. 5(a) to FIG. 5(c) and FIG. 7(a) to FIG. 7(d)

### SUMMARY OF THE INVENTION

The present invention has been made under such circumstances, and has an object to provide a technique capable of suppressing electric energy by a fundamental wave vibration and reducing phase noise in a piezoelectric oscillator using an overtone of a thickness shear vibration in a piezoelectric piece.

The present invention includes:

a piezoelectric piece generating a thickness shear vibration by application of a voltage;

an electrode on one surface side and an electrode on the other surface side provided on both surfaces of the above piezoelectric piece respectively and connected to one and the other of a power source and an earth; and

an oscillator circuit connected to these electrodes and for oscillating the piezoelectric piece in an overtone mode of a thickness shear vibration, in which

an excitation electrode portion in the electrode on the one surface side of the piezoelectric piece is composed of a first divided electrode and a second divided electrode divided apart from each other so as to be symmetrical in a direction perpendicular to a thickness shear vibration direction and electrically connected to each other,

the electrode on the other surface side of the piezoelectric piece includes excitation electrode portions that face the first divided electrode and the second divided electrode respectively and are electrically connected to each other, and

an interval between the first divided electrode and the second divided electrode is a dimension that does not generate a thickness torsional vibration mode.

The piezoelectric piece is, for example, an AT cut crystal piece, and in the above case, the first divided electrode and the second divided electrode are separated from each other in an X-axis direction being a crystal axis of a crystal.

According to the present invention, in the oscillator using an overtone of a thickness shear vibration in the piezoelectric piece being, for example, an AT cut crystal piece, the first divided electrode and the second divided electrode composing the excitation electrode portion are not provided on a vibration direction center portion of the piezoelectric piece but provided to be symmetrical to the center portion, and thereby, when obtaining an output frequency in an overtone, it is possible to suppress electric energy by a fundamental wave of both the divided electrodes and to reduce phase noise.

### BRIEF DESCRIPTION OF THE DRAWINGS

FIG. 1(a) and FIG. 1(b) are a front surface view and a rear surface view of a crystal resonator to be used in a piezoelectric oscillator of the present invention as one example;

FIG. 2 is a vertical sectional side view taken long A-A line in FIG. 1(a);

FIG. 3 is an explanatory view for indicating dimensions of electrodes of the above-described crystal resonator;

FIG. 4 is a vertical sectional side view illustrating a structure formed in a manner that the above-described crystal resonator is housed in a container;

FIG. 5 is a side view illustrating a crystal oscillator formed in a manner that the above-described structure and an oscillator circuit are mounted on a printed circuit board;

FIG. 6 is a circuit diagram illustrating the oscillator circuit to be used in the piezoelectric oscillator of the present invention as one example;

FIG. 7 is a schematic view illustrating a state of thickness shear vibrations in the above-described crystal resonator;

FIG. 8 is an explanatory view illustrating distributions of vibration energy in a fundamental wave and an overtone in the above-described crystal resonator;

FIG. 9 is an explanatory view illustrating distributions of electric energy in the fundamental wave and the overtone in the above-described crystal resonator;

FIG. 10 is an explanatory view illustrating distributions of electric energy in a fundamental wave and an overtone in a crystal resonator as a comparative example;

FIG. 11(a) and FIG. 11(b) are a front surface view and a rear surface view of a crystal resonator to be used in the piezoelectric oscillator in the present invention as another example;

FIG. 12 is a vertical sectional side view taken long B-B line in FIG. 11(a);

FIG. 13 is a circuit diagram illustrating an oscillator circuit to be used in the piezoelectric oscillator of the present invention as another example; and

FIG. 14(a) and FIG. 14(b) are a front surface view and a rear surface view of a crystal resonator to be used in the piezoelectric oscillator in the present invention as still another example.

### DETAILED DESCRIPTION OF THE PREFERRED EMBODIMENT(S)

### First Embodiment

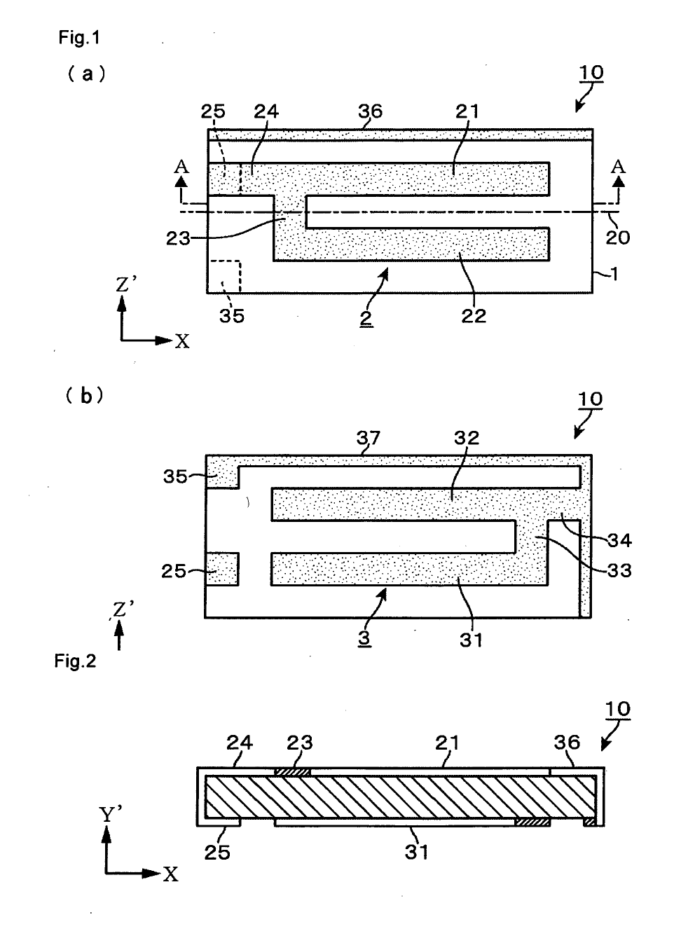

An embodiment of a crystal oscillator being a piezoelectric oscillator of the present invention will be explained. FIG. 1(a) and FIG. 1(b) illustrate one surface side and the other surface side of a crystal resonator 10 as a piezoelectric resonator to be used in the crystal oscillator, and FIG. 2 illustrates a cross section taken along A-A line in FIG. 1(a). 1 denotes an AT cut crystal piece in a strip shape (rectangular shape) being a piezoelectric piece, and the crystal piece 1 is formed in a manner that long edges thereof are along an X axis and short edges thereof are along a Z′ axis respectively. It can be said that the above rectangular-shaped crystal piece 1 is a piezoelectric piece formed symmetrically to a line extending in a direction perpendicular to a thickness shear vibration direction, namely symmetrically to the X axis. Incidentally, the Z′ axis is an axis in which a Z axis being a mechanical axis of a crystal is rotated counterclockwise at about 35 degrees and 15 minutes.

On the one surface side and the other surface side of the above-described crystal piece 1, an electrode 2 and an electrode 3 are provided respectively. As illustrated in FIG. 1(a), an excitation electrode portion in the electrode 2 on the one surface side is composed of a first divided electrode 21 and a second divided electrode 22 divided on both sides of a center line 20 passing midpoints of the short edges (in a Z′-axis direction) and extending parallel to the long edges (X axis) so as to be symmetrical to the center line 20. That is, the first divided electrode 21 and the second divided electrode 22 are separated from each other in the direction perpendicular to the thickness shear vibration direction, and are each formed in a strip shape to be parallel to each other. Then, both end portions of these divided electrodes 21, 22 are connected to a connection portion 23 extending in the Z′-axis direction, and an angular C shape is formed by them. Further, a lead-out electrode 24 is led out from the first divided electrode 21 to a short edge side of the crystal piece 1 and is led to the other surface side of the crystal piece 1 to be connected to a terminal portion 25.

As illustrated in FIG. 1(b), in the electrode 3 on the other surface side, strip-shaped excitation electrode portions 31, 32 are formed at positions (projection areas) facing the first divided electrode 21 and the second divided electrode 22 on the one surface side respectively. Both end portions of these excitation electrode portions 31, 32 are connected to a connection portion 33 to form an angular C-shaped electrode, and a lead-out electrode 34 extends toward the short edge on a side opposite to the short edge to which the lead-out electrode 24 on the one surface side is led. That is, the angular C-shaped electrode (31, 32, and 33) on the other surface side is in the direction opposite to the angular C-shaped electrode (21, 22, and 23) on the one surface side, and thus the electrode 2 on the one surface side is designed so that only the divided electrodes 21, 22 function as the excitation electrode portion.

Then, narrow conductive paths extend rightward and leftward along the short edge from the lead-out electrode 34, and the conductive path on one side is led to the one surface side of the crystal piece 1 as illustrated in FIG. 1(a) and is further formed along the long edge of the crystal piece 1. Further, as illustrated in FIG. 1(b), the conductive path on the other side extends, on the other surface side, along the long edge on a side opposite to the above-described long edge and is further bent at the short edge of the crystal piece 1 to be connected to a terminal portion 35.

The terminal portion 25 connected to the electrode 2 on the one surface side of the crystal piece 1 is connected to a DC power source side of an oscillator circuit as will be described later, and further the terminal portion 35 connected to the electrode 3 on the other surface side of the crystal piece 1 is grounded. When symbols 36, 37 are assigned to the conductive paths extending along the long edges on the both sides of the crystal piece 1 respectively and the conductive paths are called tab electrodes, in this embodiment, the tab electrodes 36, 37 to be grounded are provided on end portions of the crystal piece 1 in the Z′-axis direction respectively. Advantages of the tab electrodes 36, 37 will be described later.

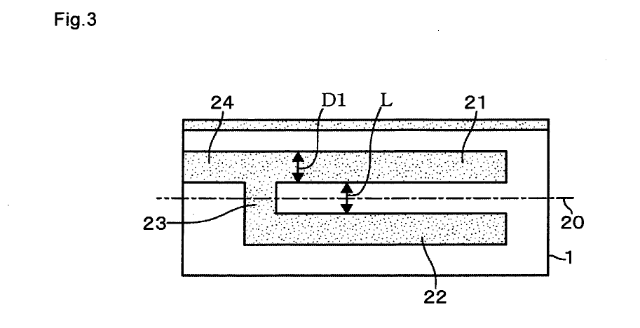

In this example, dimensions of the long edge and the short edge of the crystal piece are 9.0 mm and 6.5 mm respectively, and film thicknesses of the electrodes 2, 3 are each, for example, 4000 angstrom. Further, as illustrated in FIG. 3, a width D1 of each of the divided electrodes 21, 22 is 1.5 mm, a separation distance L between the divided electrodes 21, 22 is 1.5 mm, and a width D2 of each of the tab electrodes 36, 37 is 0.4 mm. A material of each of the electrodes 2, 3 is one in which a chromium layer is set to a base and on the chromium layer, a gold layer is stacked.

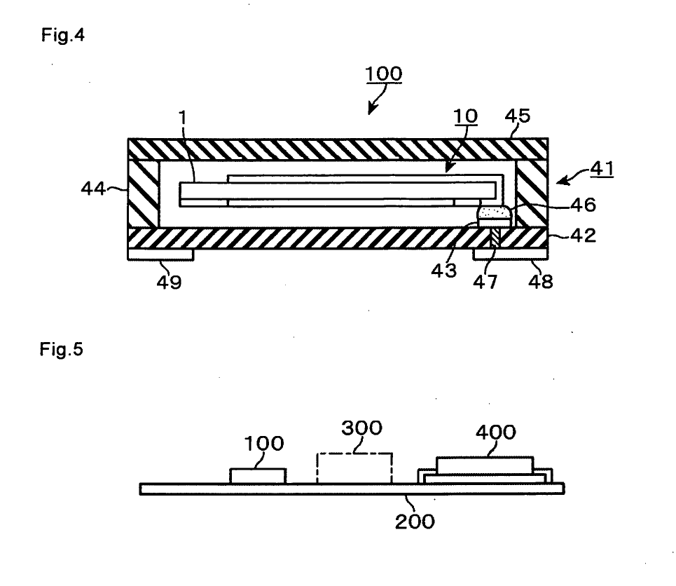

FIG. 4 illustrates a side view of a crystal electronic component 100 in which the crystal resonator 10 is mounted in a holder 41. The holder 41 is provided with a substrate 42 supporting the crystal resonator 10, electrodes 43, 43 formed on a front surface of the substrate 42 (in the drawing, the single electrode is only illustrated), a side peripheral portion 44 provided on the substrate 42 so as to surround a side periphery of the crystal resonator 10, and a cover portion 45 provided on the side peripheral portion 44. The crystal resonator 1 is supported on the front surface of the substrate 42 via conductive adhesives 46 coated on the above-described electrodes 43. 47 in the drawing denotes conductive paths provided in the substrate 42.

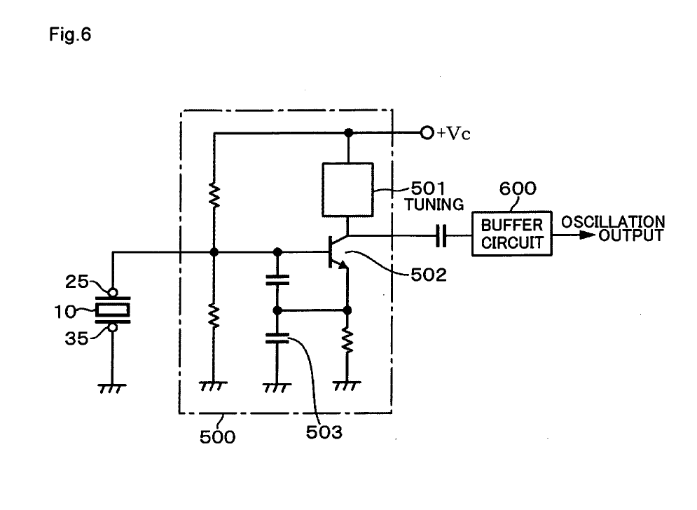

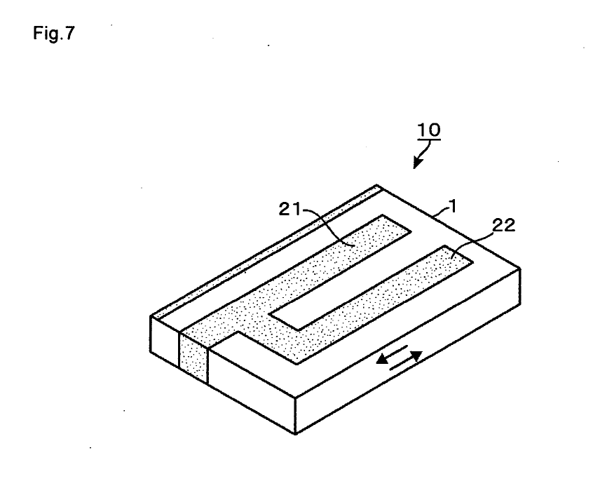

On a rear surface of the substrate 42, electrodes 48, 48 are provided (in the drawing, only one of the electrodes 43, 48 is illustrated), and the electrodes 48 are electrically connected to the terminal portion 25, 35 of the crystal resonator 10 illustrated in FIG. 1(a) and FIG. 1(b) via the conductive paths 47, the electrodes 43, and the conductive adhesives 46 respectively. 49 in the drawing denotes a dummy electrode. FIG. 5 illustrates the crystal oscillator in which the crystal electronic component 100 is mounted on a circuit board 200 to be formed with another electronic component group 300 and an IC chip 400. Further, FIG. 6 is a circuit diagram of the crystal oscillator circuit, and at both ends of the crystal resonator 10, the terminal portion 25, 35 corresponding to FIG. 1(a) and FIG. 1(b) are illustrated. 500 denotes a Colpitts oscillator circuit, and the Colpitts oscillator circuit 500 is configured so as to oscillate the crystal resonator in an overtone. 501 denotes a tuning circuit, and the turning circuit 501 is configured so as to resonate in the overtone in order to oscillate the crystal resonator. 502 denotes a transistor to be provided in, for example, the IC chip 400, which is an amplifier circuit, and an oscillation output is taken out of, for example, a collector of the transistor 502 via a buffer circuit 600. As the overtone, a third overtone, a fifth overtone, a seventh overtone, and so on are used, but the crystal resonator 10 in FIG. 1(a) and FIG. 1(b) is used to be oscillated in the third overtone.

Incidentally, as the oscillator circuit 500, a configuration in which the tuning circuit 501 is not provided, or the tuning circuit 501 is provided and then an inductor is provided in an emitter of the transistor 502 and a parallel resonance frequency of a capacitor 503 and the inductor is set to an intermediate frequency between frequencies of an overtone and a fundamental wave may also be employed.

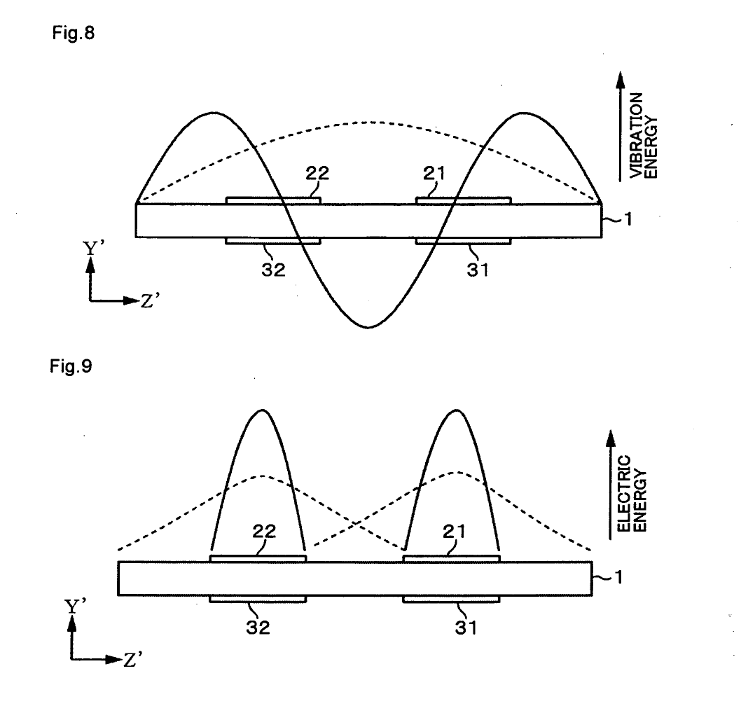

In the crystal oscillator as above, when electric fields are applied to the crystal piece 1 by the electrodes 2; 3, thickness shear vibrations vibrating in the X-axis direction and indicated by arrows in FIG. 7 occur. Then, in the case when the oscillator circuit is configured so as to oscillate in, for example, a third overtone, a distribution of vibration energy by the third overtone in the crystal piece 1 is indicated by a solid line in FIG. 8. Further, a distribution of vibration energy by a fundamental wave is indicated by a dotted line in FIG. 8. However, peak values are not exactly illustrated as a matter of convenience. Further, FIG. 9 illustrates distributions of electric energy to be generated in the divided electrodes 21, 22 being the excitation electrode portion, and solid lines each indicate the electric energy based on the third overtone, and dotted lines each indicate the electric energy based on the fundamental wave.

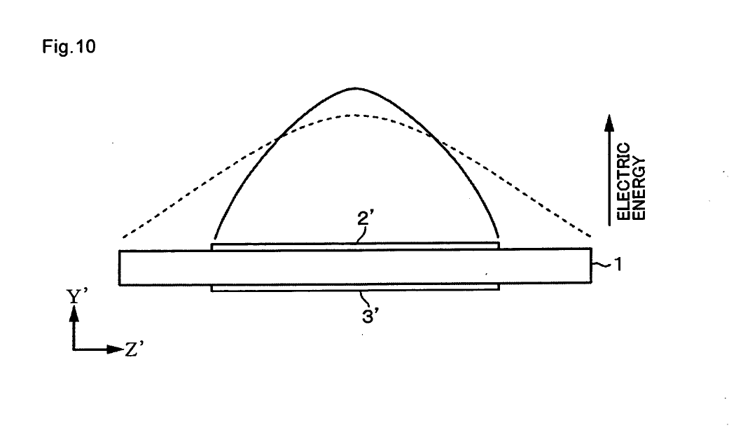

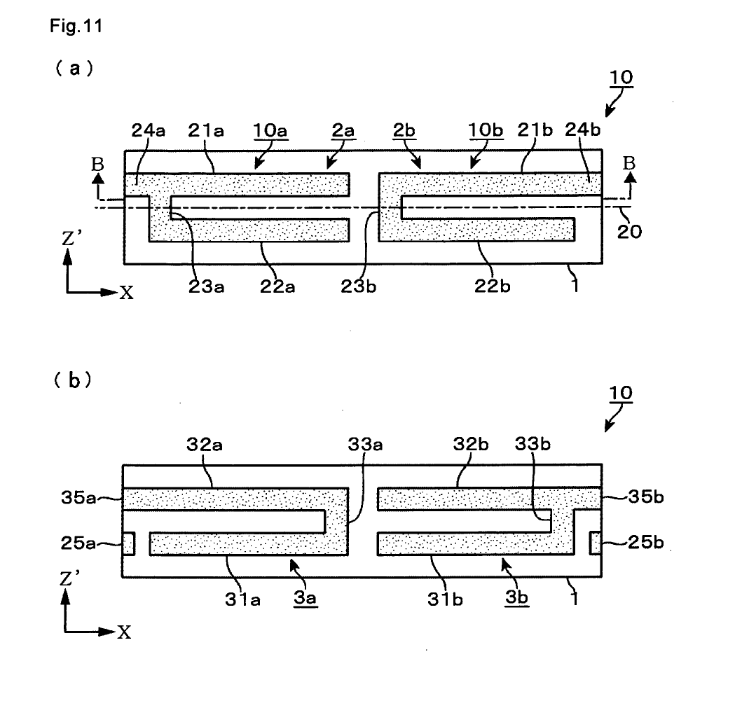

FIG. 10 illustrates distributions of electric energy in the case when excitation electrode portions are provided on a center portion of the crystal piece 1 in the Z′-axis direction. 2′, 3′ denote the excitation electrode portions. A solid line and a dotted line indicate the electric energy based on an overtone and the electric energy based on a fundamental wave respectively. In the above case, vibration energy by the fundamental wave is large, and thus the electric energy based on the fundamental wave is also large. Thus, the fundamental wave is applied to an oscillation output in the overtone to thereby increase phase noise. Thus, in this embodiment, the excitation electrode portions are each divided on the right and left sides so as to avoid the center. Incidentally, in order to obtain stable oscillation, the divided electrodes 21, 22 are preferably symmetrical to the center line 20 illustrated in FIG. 1(a).

A fundamental wave vibration also exists in the areas where the divided electrodes 21, 22 are formed, so that the electric energy by the fundamental wave also occurs in the divided electrodes 21, 22. Then, as for the electric energy by the fundamental wave, skirts of the electric energy spread over both sides of an electrode, and thus, also in the crystal resonator 10 in this embodiment, skirts of the electric energy spread over both sides of each of the divided electrodes 21, 22 as indicated by the dotted lines in FIG. 9. Thus, when the divided electrodes 21, 22 being the excitation electrode portion are disposed too close to each other, the extent to which the electric energy by the fundamental wave on one side is applied to the electric energy on the other side is increased and the phase noise is increased. Thus, the divided electrodes 21, 22 are required to be separated from each other by a certain distance or more. If a separation distance between the divided electrodes 21, 22 is too small, a thickness torsional vibration mode occurs, resulting that an object of the present invention cannot be achieved. A preferable film thickness of the excitation electrode portion is from 2000 angstrom to 10000 angstrom, and in the case of 2000 angstrom, the above-described separation distance (distance denoted by L in FIG. 3) is preferably, for example, 1.3 mm or more. If the separation distance is 1.3 mm or more, the thickness torsional vibration mode does not occur, or the thickness torsional vibration mode can be ignored.

Returning to FIG. 1(a) and FIG. 1(b) and FIG. 2, this embodiment is preferable with regard to the point in which the tab electrodes 36, 37 to be grounded are provided on the both ends of the crystal piece 1 in the Z′-axis direction, namely on the long edge sides, and thereby the electric energy by the fundamental wave flows to grounded sides via the above tab electrodes 36, 37 and thus the phase noise based on the fundamental wave is further suppressed.

As above, in the crystal resonator 10 to be used in the crystal oscillator in the above-described embodiment, the first divided electrode 21 and the second divided electrode 22 composing the excitation electrode portion are not provided on the vibration direction center portion of the crystal piece 1 but provided to be symmetrical to the center portion. Thus, when obtaining an output frequency in the overtone, the electric energy by the fundamental wave in both the divided electrodes 21, 22 are small and the divided electrodes 21, 22 are separated by a predetermined distance or more, and thus an effect of the electric energy by the fundamental wave that the divided electrode 22 (21) on the other side has on the divided electrode 21 (22) on one side is small. As a result, the phase noise based on the fundamental wave can be reduced. An oscillator using an overtone has high frequency stability with respect to temperature and excels in this point, but has a disadvantage in that the phase noise is increased due to an effect of the fundamental wave, resulting that the present invention in which the effect of the fundamental wave is suppressed is extremely effective.

Incidentally, the shape of the crystal piece 1 is not limited to a rectangular shape, and may also be, for example, a circle. Further, the shape of each of the divided electrodes 21, 22 is also not limited to the strip shape, and may also be a square, a semicircle, or the like. Further, in the above-described excitation electrode portions, the electrode 2 on the one surface side and the electrode 3 on the other surface side are connected to a power source side and an earth side respectively, but the electrode 2 on the one surface side and the electrode 3 on the other surface side may also be connected to the earth side and the power source side respectively.

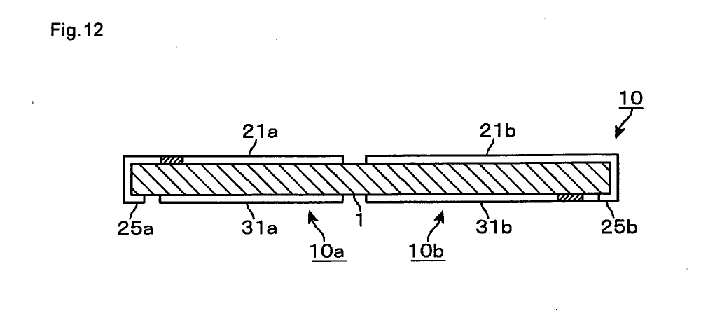

Next, another embodiment of the crystal oscillator being the piezoelectric oscillator of the present invention will be explained with reference to FIG. 11(a) and FIG. 11(b) to FIG. 13. In this embodiment, as a crystal resonator 10, one in which two sets each composed of an excitation electrode portion on one surface side and an excitation electrode portion on the other surface side are provided on a crystal piece 1 is used. FIG. 11(a) and FIG. 11(b) are plan views illustrating the one surface side and the other surface side of the crystal resonator 10 respectively. The crystal resonator 10 illustrated in FIG. 11(a) and FIG. 11(b), schematically speaking, is one in which two sets each composed of the electrodes 2, 3 illustrated in FIG. 1(a) and FIG. 1(b) are arranged apart from each other on the single crystal piece 1 in the X-axis direction, and a terminal portion for connecting to conductive paths of the electrodes of the set on one side is formed on one short edge side of the crystal piece 1 and a terminal portion for connecting to conductive paths of the electrodes of the set on the other side is formed on the other short edge side of the crystal piece 1.

In FIG. 11(a) and FIG. 11(b), symbols of Arabic numerals correspond to the same symbols of Arabic numerals in FIG. 1(a) and FIG. 1(b), and symbols of “a” and “b” that are added after the symbols are symbols for distinguishing between the set on one side and the set on the other side respectively. Then, the above crystal resonator 10 is not provided with tab electrodes as is the crystal resonator 10 in FIG. 1(a) and FIG. 1(b), so that a layout where electrodes are led out differs from that in FIG. 1(a) and FIG. 1(b), but the point, in which first divided electrodes 21a (b) and second divided electrodes 22a (b) are formed on the one surface side of the crystal piece 1 symmetrically to a center line 20, and angular C shapes of the electrodes 2a (2b) on the one surface side are set in the direction opposite to those of the electrodes 3a (3b) on the other surface side, and only the portions where these divided electrodes 21a (b), 22a (b) are formed function as the excitation electrode portion, is similar to that in the above embodiment. 10a denotes a main vibration area to be excited by the electrodes 2a and 3a, and 10b denotes an auxiliary vibration area to be excited by the electrodes 2b and 3b. Incidentally, “main”, “auxiliary” are added as a matter of convenience in order to avoid confusion of terms, and do not indicate a master-servant relationship functionally.

In the above embodiment, the crystal resonator 10 is held in the holder 41 in a cantilever structure, but the crystal resonator 10 in FIG. 11(a) and FIG. 11(b) is held in the holder 41 in a double cantilever structure. As an applied example of the crystal resonator 10 as above, for example, methods to be described in (1), (2) below can be cited.

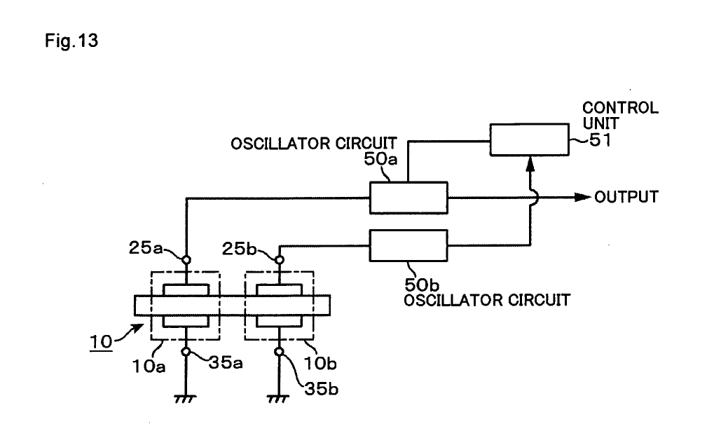

(1) An oscillation output corresponding to the vibration area 10a on one side is used as an output signal of the oscillator, and an oscillation output corresponding to the vibration area 10b on the other side is used as a temperature sensor signal. Concretely, as illustrated in FIG. 13, two oscillator circuits 50a and 50b are prepared corresponding to the main vibration area 10a and the auxiliary vibration area 10b respectively, and an oscillation output of the oscillator circuit 50b on the other side is converted into a temperature signal in a control unit 51. As for the conversion, by previously finding a temperature characteristic of the oscillation output (a frequency), a temperature at that moment is obtained in the control unit 51 based on the oscillation output. Then, a difference between the detected temperature and a reference temperature is obtained, and based on a frequency temperature characteristic in the oscillator circuit 50a on one side, a change in frequency corresponding to the difference between the above-described temperatures is obtained, and a compensation voltage of a control voltage determined at the reference temperature (reference control voltage) is obtained so as to cancel the above change, and the compensation voltage is added to the reference control voltage to be set to a control voltage of the oscillator circuit 50a on one side. The respective vibration areas 10a, 10b are formed in the same crystal piece 1 and have the same temperature substantially, so that an oscillation frequency of the oscillator circuit 50a exhibits high stability with respect to a temperature change. Incidentally, the vibration areas 10a, 10b each may also be oscillated in an overtone with the same order, or each may also be oscillated in overtones different from each other, (in, for example, a third overtone on one side and a fifth overtone on the other side, or the like).

(2) The method will be explained by using part of a circuit in FIG. 13. A difference between the oscillation outputs in the oscillator circuits 50a, 50b is taken out in a mixer, and a difference frequency is used as an output frequency. In the above case, the output frequency may also be multiplied in, for example, a multiplication circuit to be used. Further, the vibration areas 10a, 10b each may also be oscillated in an overtone with the same order, or each may also be oscillated in overtones different from each other, (in, for example, a third overtone on one side and a fifth overtone on the other side, or the like). Even in the case of using an overtone with the same order, positions of both the vibration areas differ, so that the difference frequency is generated. Also in such an example, the respective vibration areas 10a, 10b are formed in the same crystal piece 1 and have the same temperature substantially, so that temperature characteristics of oscillation frequencies in both the vibration areas 10a, 10b are cancelled and thereby a frequency that is stable with respect to a temperature change is obtained.

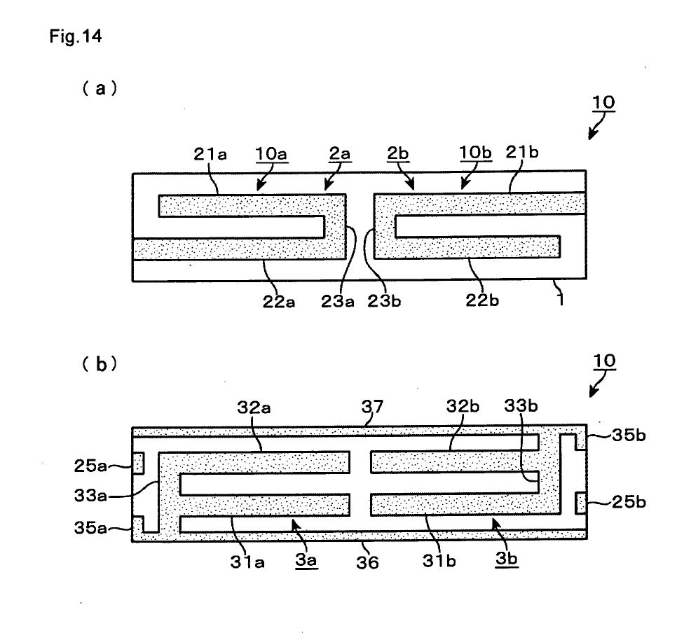

Further, also in what is called a twin sensor provided with the main vibration area 10a and the auxiliary vibration area 10b as above, tab electrodes may be provided as is the embodiment in FIG. 1(a) and FIG. 1(b). Such a structure is illustrated in FIG. 14(a) and FIG. 14(b). In this example, tab electrodes 36, 37 are provided on the other surface side of a crystal piece 1 along long edges of the crystal piece 1, and these tab electrodes 36, 37 are grounded. Further, in the example in FIG. 14(a) and FIG. 14(b), angular C-shaped electrodes in electrodes 2a, 2b on one surface side of the crystal piece 1 are disposed so that connection portions 23a, 23b are positioned on a center side.

Further, in the above-described example, the AT cut crystal piece is used as the piezoelectric piece, but as long as the piezoelectric piece is to generate the thickness shear vibrations, an effect of the present invention is obtained, so that, for example, a BT cut crystal piece may also be applied. Further, the piezoelectric piece is not limited to the crystal piece, and may also be a ceramic or the like.

### Experimental Example

The structure illustrated in FIG. 11(a) and FIG. 11(b) was manufactured as the crystal resonator. In the above structure, two of the set of the electrodes illustrated in FIG. 1(a) and FIG. 1(b) are used, so that a length dimension of each of the electrodes differs from that explained in FIG. 3, but dimensions other than the length dimension (the dimensions of the crystal piece, the width D1 of the divided electrode, and the separation distance L) are the same. Further, as for the structure of each of the electrodes, a chromium film was formed to have a thickness of 50 angstrom, and on the chromium film, a gold film with a thickness of 2000 angstrom was stacked. Then, the crystal resonator was formed so that the two vibration areas 10a, 10b vibrate in a third overtone (54 MHz) and a fifth overtone (90 MHz) respectively.

Frequencies and signal strength were examined by a spectrum analyzer. Then, from obtained spectrums, values of series resistance R1 as equivalent circuit constants obtained when both the vibration areas oscillate in a fundamental wave vibration mode, a third overtone vibration mode, and a fifth overtone vibration mode were calculated. In the vibration area 10a on one side, the above-described series resistance values R1 in the fundamental wave vibration mode, the third overtone vibration mode, and the fifth overtone vibration mode were 125Ω, 16Ω, and 37Ω respectively. Further, in the vibration area 10b on the other side, the above-described series resistance values R1 in the fundamental wave vibration mode, the third overtone vibration mode, and the fifth overtone vibration mode were 130Ω, 18Ω, and 39Ω respectively. Thus, it is found that the series resistance value in the fundamental wave vibration mode is higher than those in the overtones and the fundamental wave vibration is suppressed. Accordingly, the effect of the present invention is confirmed.

What is claimed is:

1. A piezoelectric oscillator comprising:
a piezoelectric piece generating a thickness shear vibration by application of a voltage;
an electrode on one surface side and an electrode on the other surface side provided on both surfaces of said piezoelectric piece respectively and connected to one and the other of a power source and an earth respectively; and
an oscillator circuit connected to said electrodes and for oscillating said piezoelectric piece in an overtone mode of a thickness shear vibration, wherein
an excitation electrode portion in said electrode on the one surface side of said piezoelectric piece is composed of a first divided electrode and a second divided electrode divided apart from each other so as to be symmetrical in a direction perpendicular to a thickness shear vibration direction and electrically connected to each other,
said electrode on the other surface side of said piezoelectric piece includes excitation electrode portions that face the first divided electrode and the second divided electrode respectively and are electrically connected to each other, and
an interval between the first divided electrode and the second divided electrode is a dimension that does not generate a thickness torsional vibration mode.

2. The piezoelectric oscillator according to claim 1, wherein
said piezoelectric piece is an AT cut crystal piece, and the first divided electrode and the second divided electrode are separated from each other in a Z′-axis direction.

3. The piezoelectric oscillator according to claim 1, wherein
the first divided electrode and the second divided electrode are formed in strip shapes extending parallel to each other.

4. The piezoelectric oscillator according to claim 1, wherein
said electrode on the one surface side includes a connection portion connecting both one end side of the first divided electrode and one end side of the second divided electrode, and
in said electrode on the other surface side, an electrode portion does not exist in an area facing the connection portion.
